(19) United States
(12) Patent Application Publication
(10) Pub. No.: US 2013/0270111 A1
(43) Pub. Date: Oct. 17, 2013

(54) SPUTTERING DEVICE

(71) Applicants: Bo-Hwan PARK, Yongin-si (KR); Woo-Su LEE, Yongin-si (KR)

(72) Inventors: Bo-Hwan PARK, Yongin-si (KR); Woo-Su LEE, Yongin-si (KR)

(21) Appl. No.: 13/740,596

(22) Filed: Jan. 14, 2013

(30) Foreign Application Priority Data
Apr. 13, 2012 (KR) 10-2012-0038416

(51) Int. Cl. C23C 14/56

(52) U.S. Cl. CPC C23C 14/56
USPC 204/298.23

(57) ABSTRACT

A sputtering device, including a chamber providing a reaction space, a sputter unit including a target disposed in the chamber, and a conveying unit including a plurality of rollers for supporting a substrate and for conveying the substrate relative to the target along a first direction, the conveying unit including fixed roller units having a predetermined diameter, and a variable roller unit having a diameter that changes in a second direction at both ends thereof, the second direction being orthogonal to the first direction.

### CROSS-REFERENCE TO RELATED APPLICATION

This application claims priority under 35 U.S.C. §119 to Korean Patent Application No. 10-2012-0038416, filed on Apr. 13, 2012, in the Korean Intellectual Property Office, and entitled: “Sputtering Device,” the entire contents of which is incorporated herein by reference.

### BACKGROUND

1. Field

Embodiments relate to a sputtering device.

2. Description of the Related Art

A sputtering device may be used to manufacture a thin film for various electronic elements, for example, a light absorbing layer of a solar cell. The solar cell may be a photoelectric transformation element that produces electricity by using sunlight. As an example of a solar cell, a CIGS (Cu—In—Ga—Se) solar cell may have high absorbance and electro-optical stability, and thus may have improved photoelectric transformation efficiency and durability.

### SUMMARY

Embodiments are directed to a sputtering device, including a chamber providing a reaction space, a sputter unit including a target disposed in the chamber, and a conveying unit including a plurality of rollers for supporting a substrate and for conveying the substrate relative to the target along a first direction, the conveying unit may include fixed roller units having a predetermined diameter, and a variable roller unit having a diameter that changes in a second direction at both ends thereof, the second direction being orthogonal to the first direction.

The variable roller unit may be positioned directly across from target, and the fixed roller units may be positioned at both sides of the variable roller unit in the first direction, and the fixed roller units may include first rollers, each of the first rollers may have the predetermined diameter.

The variable roller unit may include at least three second rollers, and each of the second rollers may have a fixed diameter portion, and variable diameter portions connected to both ends of the fixed diameter portion, the variable diameter portions may have a diameter that increases for the variable diameter portions farther from the fixed diameter portion.

A maximum diameter of the variable diameter portions may increase for the second rollers closer to a center of the variable roller unit.

The fixed diameter portion may have a diameter that is less than or equal to the predetermined diameter.

The variable roller unit may include at least three third rollers, and each of the third rollers may have a fixed diameter portion, and variable diameter portions connected to both ends of the fixed diameter portion, the variable diameter portions may have a diameter that decreases for the variable diameter portions farther from the fixed diameter portion.

A minimum diameter of the variable diameter portions may decrease for third rollers closer to a center of the variable roller unit.

The fixed diameter portion may have a diameter that is the predetermined diameter.

A maximum diameter of the variable roller unit may be the predetermined diameter.

A minimum diameter of the variable roller unit may be the predetermined diameter.

A center of a rotational axis of the fixed roller units and a center of a rotational axis of the variable roller unit may be at the same height in a third direction, and the third direction may be orthogonal to the first and second directions.

The fixed roller units and the variable roller unit may have the same length along the second direction.

Embodiments are also directed to a sputtering device, including a chamber providing a reaction space, a sputter unit including a target disposed in the chamber, and a conveying unit including a plurality of rollers for supporting a substrate and for conveying the substrate relative to the target along a first direction, the conveying unit may include fixed roller units having a predetermined length along a second direction, the second direction being orthogonal to the first direction, and a variable roller unit having at least two lengths along the second direction that are different from the predetermined length.

The variable roller unit may be positioned directly across from target, the fixed roller units may be positioned at both sides of the variable roller unit in the first direction, and the fixed roller units may include first rollers, each of the first rollers may have the predetermined length.

The variable roller unit may include at least three fourth rollers, the fourth rollers may have a length shorter than the predetermined length, and the fourth rollers may have a diameter that decreases for the fourth rollers closer to a center of the variable roller unit.

The variable roller unit may include at least three fourth rollers, the fourth rollers may have a length shorter than the predetermined length, and a diameter of the first rollers may be the same as a diameter of the fourth rollers.

Centers of the first rollers and the fourth rollers in the second direction may be positioned in a straight line in the first direction.

Embodiments are also directed toward a sputtering device, including a chamber providing a reaction space, a sputter unit including a target disposed in the chamber, and a conveying unit including a plurality of rollers for supporting a substrate, and for conveying the substrate relative to the target in a first direction, the conveying unit may include a variable roller unit, and may be configured to bend the substrate in a second direction, the second direction being orthogonal to the first direction.

The variable roller unit may be positioned directly across from target.

At least one selected from the group of a length and a diameter of the variable roller unit may change in the second direction.

### BRIEF DESCRIPTION OF THE DRAWINGS

Features will become apparent to those of skill in the art by describing in detail exemplary embodiments with reference to the attached drawings in which:

FIG. 1 illustrates a schematic view of a sputtering device according to an embodiment.

FIG. 2 illustrates a schematic top plan view of a target and a substrate in the sputtering device of FIG. 1.

FIG. 3 illustrates a schematic perspective view of a conveying unit in the sputtering device of FIG. 1.

FIG. 4 illustrates a schematic view of a variable roller unit, the substrate, and the target in the sputtering device of FIG. 1 in the axial direction.

FIG. 5 illustrates a schematic view of the variable roller unit and the substrate in the sputtering device of FIG. 1 in the conveying direction.

FIG. 6 illustrates a schematic perspective view of a conveying unit in a sputtering device according to an embodiment.

FIG. 7 illustrates a schematic view of the conveying unit and the substrate of FIG. 6 in the conveying direction.

FIG. 8 illustrates a perspective view of a conveying unit in a sputtering device according to an embodiment.

FIG. 9 illustrates a schematic view of a variable roller unit, a substrate, and a target in the sputtering device of FIG. 8 in the axial direction.

FIG. 10 illustrates a schematic view of the variable roller unit and the substrate in the sputtering device of FIG. 8 in the conveying direction.

FIG. 11 illustrates a schematic perspective view showing a conveying unit in a sputtering device according to an embodiment.

FIG. 12 illustrates a schematic view showing a variable roller unit, a substrate, and a target in the sputtering device of FIG. 11 in the axial direction.

FIG. 13 illustrates a schematic view showing the variable roller unit and the substrate in the sputtering device of FIG. 11 in the conveying direction.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

As used herein, the term “and/or” includes any and all combinations of one or more of the associated listed items. Expressions such as “at least one of,” when preceding a list of items, modify the entire list of items and do not modify the individual items of the list.

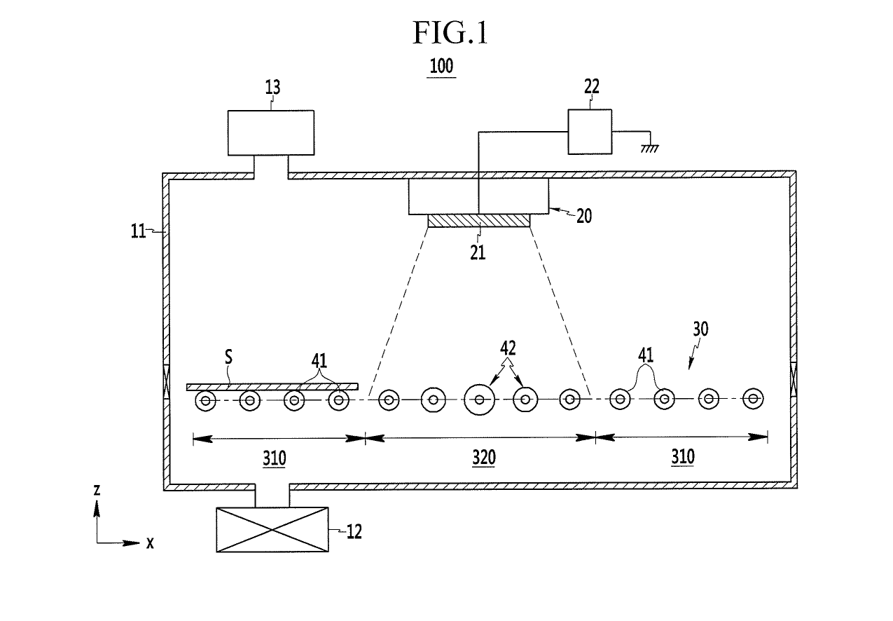

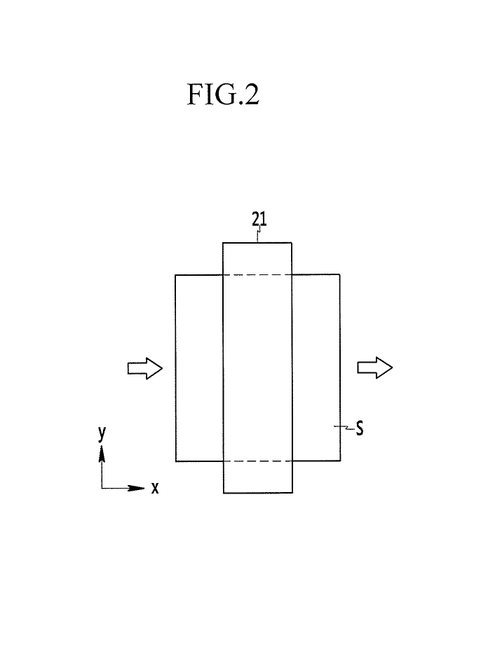

FIG. 1 illustrates a schematic view of a sputtering device according to an embodiment; FIG. 2 illustrates a schematic top plan view of a target and a substrate in the sputtering device of FIG. 1.

Referring to FIGS. 1 and 2, a sputtering device 100 may include a chamber 11 providing a reaction space, a sputter unit 20 including a target 21 and a power supply unit 22, and a conveying unit 30 for conveying a substrate S. Also, the sputtering device 100 may further include a vacuum pump 12 and a gas inlet 13 that are connected with the chamber 11.

The chamber 11 may provide a reaction space where deposition is performed and may be connected with the vacuum pump 12, such that the internal space can be exhausted. The inside of the chamber may maintain a degree of vacuum of about 10⁻⁶-10⁻⁷ torr when the deposition process is performed. The gas inlet 13 may supply an inert gas, such as an argon (Ar) gas, into the chamber 11.

The target 21 may be made of a material that is to be formed on the substrate S as a thin film. For example, if the sputtering device 100 is for manufacturing a light absorbing layer of a CIGS (Cu—In—Ga—Se) solar cell, the target 21 may be made of any one of copper, indium, copper-gallium, and the like. Further, if the sputtering device 100 is for manufacturing a reflection electrode of the CIGS solar cell, the target 21 may be made of molybdenum.

The power unit 22 may supply a voltage to the target 21 to ionize the inert gas. As a source of the power unit 22, a direct current (DC) power unit or radio frequency (RF) power unit may be used.

The substrate S may be made of glass, macromolecular film, metal, and the like, and may be a large substrate with both longitudinal and transverse lengths of about 1 m or more. Further, the substrate S may be thin, e.g., have a thickness of about 3 mm or less, and may be flexible.

The substrate may have a longitudinal length in the conveying direction (x-axial direction) and a transverse direction in the direction perpendicular to the conveying direction (y-axial direction). Although FIG. 2 illustrates the transverse direction of the substrate S as being longer than the longitudinal direction, the shape of the substrate S may be a suitable shape other than the shape illustrated in FIG. 2.

The substrate S may be conveyed at a predetermined speed under the target 21 by the conveying unit 30, and at a predetermined distance from the target 21. The target 21 may be suitable for a large substrate, e.g., a bar-shaped target. The bar-shaped target may be formed to have a length longer than the transverse length of the substrate S.

A plurality of rollers 41 and 42 constituting the conveying unit 30 may be disposed such that the axial direction (y-axial direction) coincides with the length direction of the target 21, and may be positioned in parallel at a predetermined distance from each other. The plurality of rollers 41 and 42 may be rotated at a predetermined speed by receiving power from a driving unit, which is not shown.

When a voltage is applied to the target 21, the inert gas flowing into the chamber 11 may be ionized, and the ionized gas may be accelerated by the voltage and may hit the surface of the target 21. In this process, atoms of the material of the target 21 are ejected from the target and deposited on the substrate S, thereby forming a thin film. A magnet (not shown) may be disposed on the rear side of the target 21. The magnet may increase deposition efficiency by confining electrons, which may be created in the chamber 11, around the target 21.

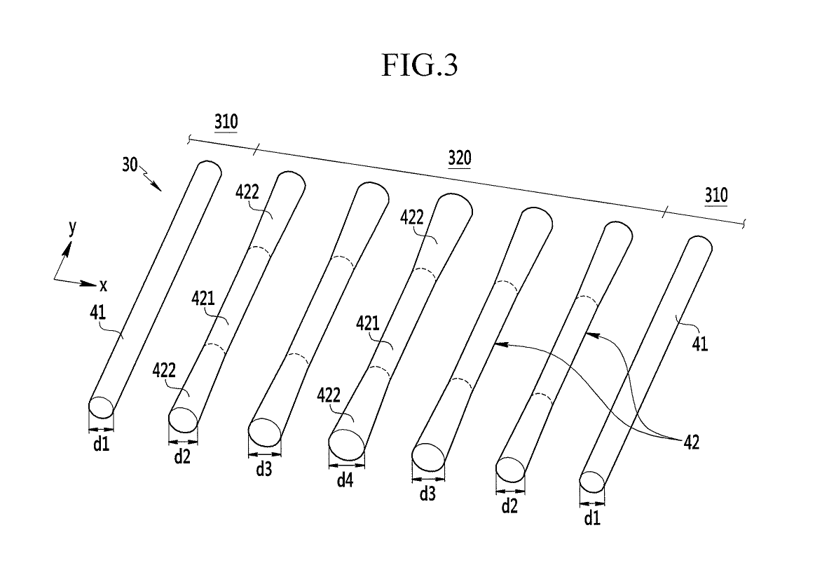

FIG. 3 illustrates a schematic perspective view of a conveying unit in the sputtering device of FIG. 1.

Referring to FIGS. 1 and 3, the conveying unit 30 may include fixed roller units 310 having a predetermined diameter and a variable roller unit 320 having diameters that change at both ends in the axial direction thereof. In this configuration, the center of the rotational axis of the fixed roller unit 310 and the center of the rotational axis of the variable roller unit 320 both may be positioned at the same height (i.e., in the z-axial direction).

The variable roller unit 320 may be positioned directly under the target 21 and the fixed roller units 310 may be positioned at both sides (the left and right in FIG. 3) of the variable roller unit 320 in the conveying direction (x-axial direction). That is, the variable roller unit 320 may be closer to the target 21 than the fixed roller units 310. The center of the variable roller unit 320 may coincide with the center of the target 21 in the height direction (z-axial direction) of the sputtering device 100.

The fixed roller unit 310 may include two or more first rollers 41. All of the first rollers 41 may have the same diameter and may have a predetermined diameter in the axial direction (y-axial direction). The diameters of the first rollers 41 are indicated by d1 in FIG. 3.

The variable roller unit 320 may include three or more second rollers 42. The second rollers 42 each may have a fixed diameter portion 421 at the center thereof, and a variable diameter portion 422 connected to both ends of the fixed diameter portion 421. The fixed diameter portion 421 may have the same diameter d1 as that of the first rollers 41. The fixed diameter portions 421 of the second rollers 42 may be formed to have the same length and the variable diameter portions 422 thereof may also be formed to have the same length. An overall length of each of the first rollers 41 and the second rollers 42 may be the same.

The variable diameter portions 422 may increase in diameter for the variable diameter portions 422 farther from the fixed diameter portion 421. Further, the maximum diameter of the variable diameter portions 422 may increase for second rollers 42 closer to the center of the variable roller unit 320 (farther from the first rollers 41). The maximum diameter of the variable diameter portions 422 of each of the second rollers 42 may be the diameter measured at the end thereof.

Although FIG. 3 shows an example where the variable roller unit 320 is composed of five second rollers 42, the number of second rollers 42 may be a suitable number other than five. The variable diameter portions 422 of the second rollers 42 shown in FIG. 3 have the maximum diameters d2, d3, d4, d3, and d2 in the conveying direction of the substrate (x-axial direction), and the maximum diameters may satisfy the condition, d4>d3>d2>d1.

As described above, the variable roller unit 320 may have diameters that change in the conveying direction (x-axial direction) while having diameters that change in the axial direction (y-axial direction) at both ends (at the variable diameter portions 422). The changes in diameter of the variable diameter portions 422 in the axial direction (y-axial direction) may increase the deposition uniformity of the thin film, and the changes in diameter of the variable diameter portions 422 in the conveying direction (x-axial direction) may increase conveying efficiency, e.g., of the substrate S.

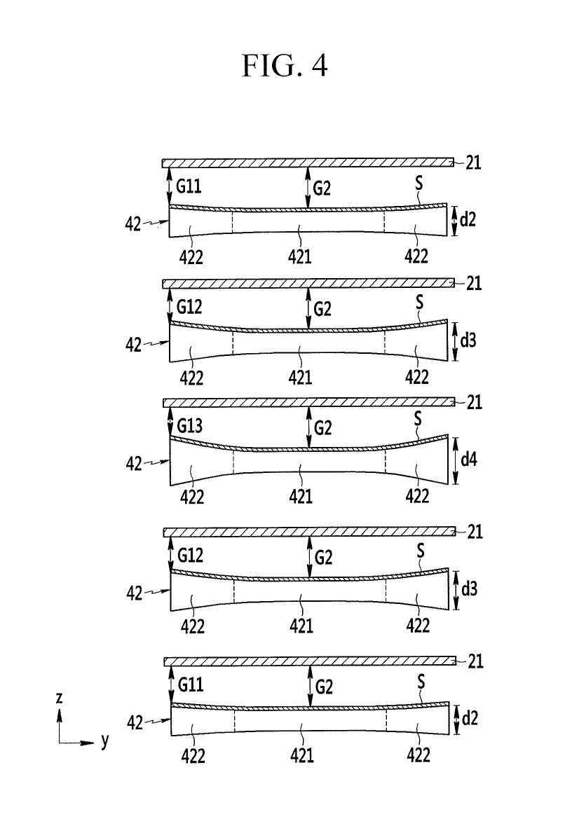

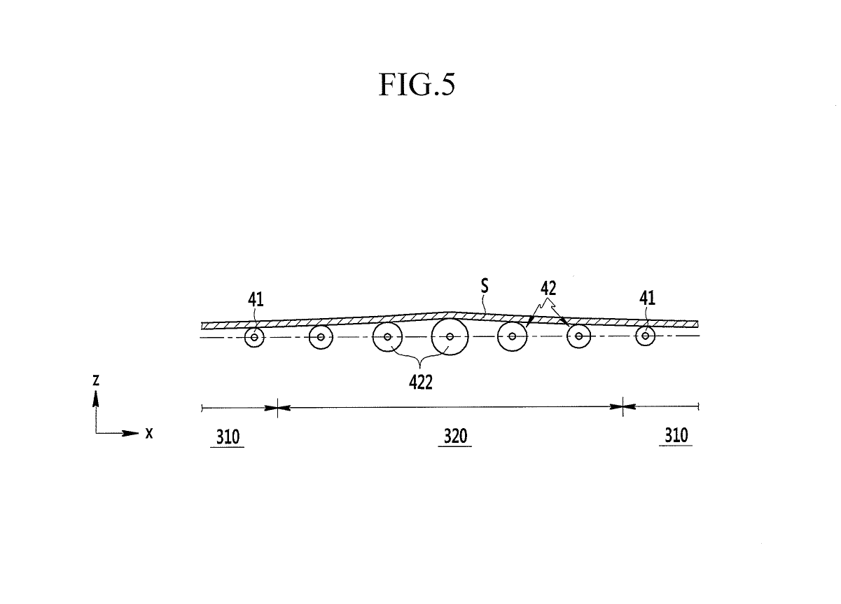

FIG. 4 illustrates a schematic view of a variable roller unit, the substrate, and the target in the sputtering device of FIG. 1 in the axial direction; FIG. 5 illustrates a schematic view of the variable roller unit and the substrate in the sputtering device of FIG. 1 in the conveying direction.

Referring to FIGS. 4 and 5, the variable diameter portions 422 of the second rollers 42 may have diameters that increase for the variable diameter portions 42 farther from the fixed diameter portion 421. Thus, both end areas of the substrate S seated on the second rollers 42 (which areas correspond to the variable diameter portions 422) may bend up and the substrate S may be conveyed in the bent state under the target 21. Both end areas of the substrate S in the axial direction may be positioned higher than the center portion thereof, such that the distance from the target 21 decreases.

In FIG. 4, the distance between the center portion of the substrate S and the target 21 is indicated by G2 and the distances between both ends of the substrate and the target 21 are indicated by G11, G12, and G13. The distances between the substrate S and the target 21 may satisfy the conditions: G11<G2, G12<G2, and G13<G2.

Further, the variable diameter portions 422 of the second rollers 42 may have maximum diameters that increase for the second rollers 42 closer to the center of the variable roller unit 320. Thus, the degree of bending at both end areas of the substrate S seated on the second rollers 42 (which areas correspond to the variable diameter portions 422) may have a maximum value at the center of the variable roller unit 320 and may have smaller values farther from the center of the variable roller unit 320.

The distances between the substrate S and the target in FIG. 4 may satisfy the condition, G11>G12>G13. Further, as illustrated in FIG. 5, both end areas of the substrate S seated on the second rollers 42 (which areas correspond to the variable diameter portions 422) may bend up and then bend down in the conveying direction (x-axial direction).

When a thin film is deposited by using a sputtering unit without the variable roller unit 320, the thicknesses of the thin film measured at both ends of the substrate S may be thinner than the thickness of the thin film measured at the center portion.

The sputtering device according to an embodiment that includes the variable roller unit 320 may make the thicknesses of the thin film measured at both ends of the substrate S relatively thick. Thus, the thicknesses of the thin film formed on the center portion and both ends may be uniform. Accordingly, the sputtering device 100 according to an embodiment may increase the deposition uniformity of the thin film in the axial direction (y-axial direction) by using the variable roller unit 320.

Also, the substrate S may not be smoothly conveyed if the substrate S is bent only in the axial direction (y-axial direction) in order to increase the deposition uniformity of the thin film. It may be difficult to convey the substrate S if the substrate S has an increased size and/or decreased thickness. The variable diameter portions 422 of the variable roller unit 320 may also bend the substrate S in the conveying direction (x-axial direction), and thus the substrate may be smoothly conveyed, even if the substrate is a large-sized and/or thin substrate.

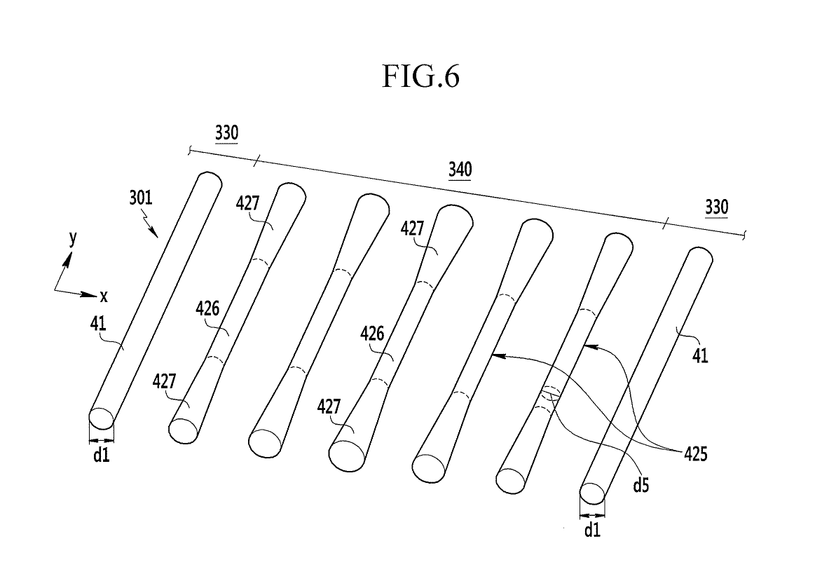

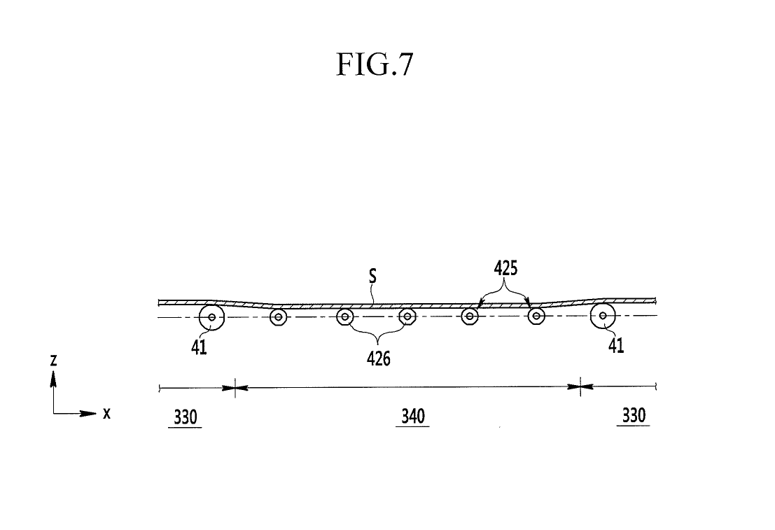

FIG. 6 illustrates a schematic perspective view of a conveying unit in a sputtering device according to an embodiment; FIG. 7 illustrates a schematic view of the conveying unit and the substrate of FIG. 6 in the conveying direction. Aspects of the sputtering device illustrated in FIGS. 6 and 7 may be the same as the aspects of the sputtering device discussed above, and a detailed description of these aspects will not be repeated.

Referring to FIG. 6 and FIG. 7, a conveying unit 301 may have the same configuration as the conveying unit 30 discussed above, except that the fixed diameter portions 426 of the second rollers 425 may be formed to have smaller diameters than the diameters of the first rollers 41. The fixed diameter portions 426 of the second rollers 425 may all have the same diameter.

The diameters of the fixed diameter portions 426 are indicated by d5 in FIG. 6, and the first rollers 41 and the second rollers 425 may satisfy the condition, d1>d5. Variable diameter portions 427 in FIG. 6 may have the same diameter as in FIG. 3.

If the fixed diameter portions 426 are formed to have a smaller diameter than that of the first rollers 41, the center area of the substrate S (which corresponds to the fixed diameter portions 426) may bend slightly down when being conveyed on the variable diameter unit 340 from the fixed roller unit 330, and may bend slightly up again when being conveyed on the fixed roller unit 330 from the variable roller unit 340.

The conveying unit 301 as described in the preceding paragraph may smoothly convey a large-sized substrate in accordance with the bend of the substrate S, and may substantially minimize a defect in the conveying of the substrate S.

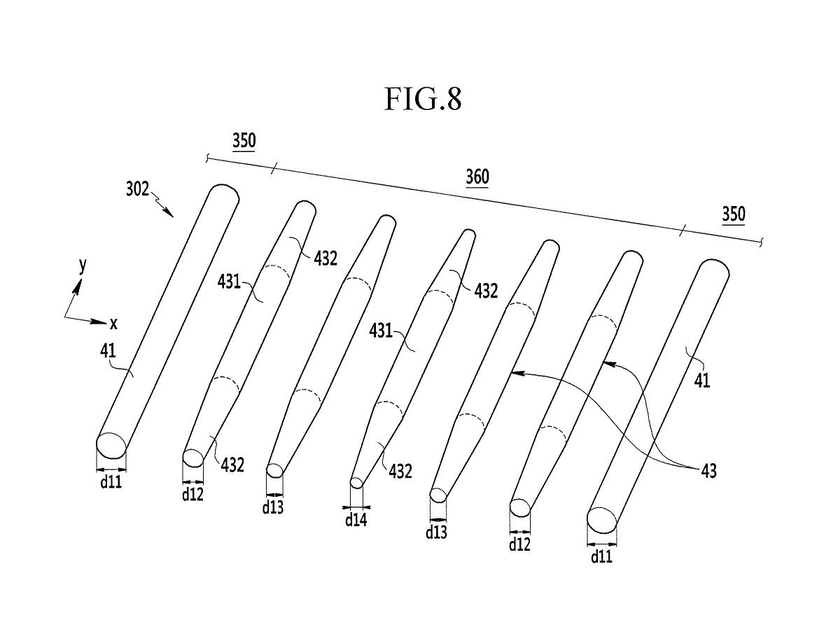

FIG. 8 illustrates a perspective view of a conveying unit in a sputtering device according to an embodiment. Aspects of the sputtering device illustrated in FIG. 8 may be the same as the aspects of the sputtering device discussed above, and a detailed description of these aspects will not be repeated.

Referring to FIG. 8, a conveying unit 302 may include fixed roller units 350 and a variable roller unit 360. The fixed roller units 350 may include two or more first rollers 41 and may have the same configuration as discussed above. The diameters of the first rollers 41 are indicated by d11 in FIG. 8.

The variable roller unit 360 may include three or more third rollers 43. The third rollers 43 each may have a fixed diameter portion 431 at the center thereof, and variable diameter portions 432 connected to both ends of the fixed diameter portion 431. The fixed diameter portion 431 may have a diameter d11 that is the same as that of the first rollers 41. The fixed diameter portions 431 of the third rollers 43 may be formed to have the same length, and the variable diameter portions 432 of the third rollers 43 may also be formed to have the same length.

The variable diameter portions 432 may decrease in diameter for the variable diameter portions 432 farther from the fixed diameter portion 431. Further, the minimum diameter of the variable diameter portions 432 may decrease for the third rollers 43 closer to the center of the variable roller unit 360 (farther from the first rollers 41). The minimum diameter of the variable diameter portions 432 of each of the third rollers 43 may be the diameter measured at ends thereof.

Although FIG. 8 shows an example where the variable roller unit 320 is composed of five third rollers 43, the number of third rollers 43 may be a suitable number other than five. The variable diameter portions 432 of the third rollers 43 shown in FIG. 8 have minimum diameters d12, d13, d14, d13, and d12 in the conveying direction (x-axial direction), and the minimum diameters may satisfy the condition, d11>d12>d13>d14.

As described above, the variable roller unit 360 may have diameters that change in the axial direction (y-axial direction) at both ends at the variable diameter portions 432, and in the conveying direction (x-axial direction).

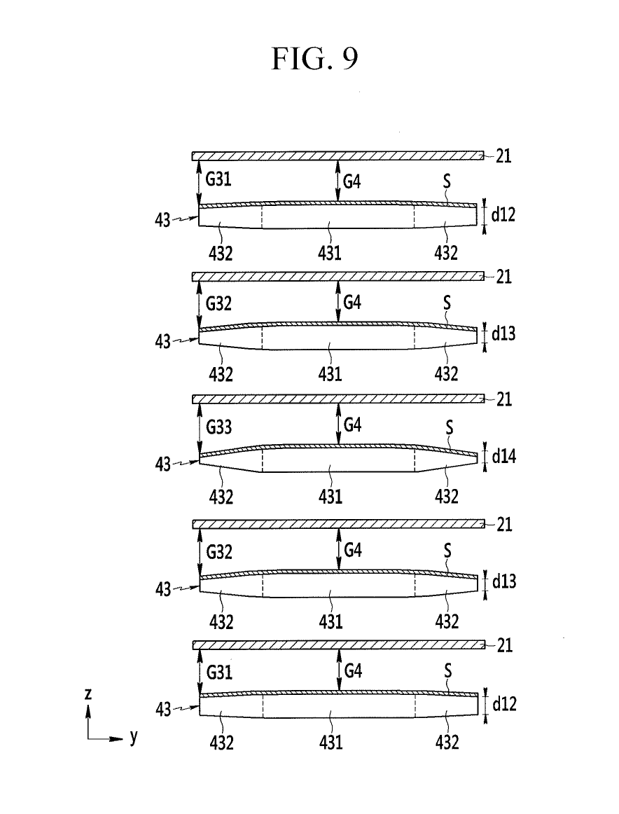

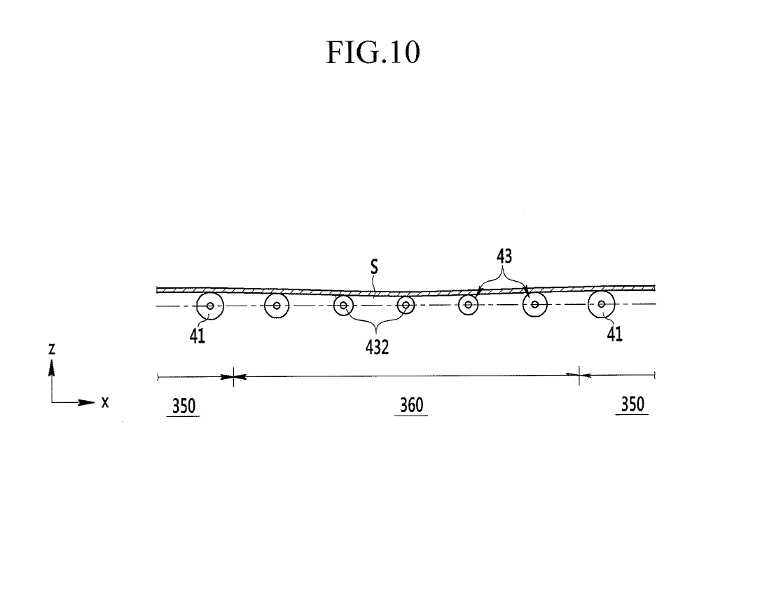

FIG. 9 illustrates a schematic view of a variable roller unit, a substrate, and a target in the sputtering device of FIG. 8 in the axial direction; FIG. 10 illustrates a schematic view of the variable roller unit and the substrate in the sputtering device of FIG. 8 in the conveying direction.

Referring to FIGS. 9 and 10, the variable diameter portions 432 of the third rollers 43 may have a diameter that decreases for variable diameter portions 432 farther from the fixed diameter portion 431. Thus, both end areas of the substrate S seated on the third rollers 43 (which areas correspond to the variable diameter portions 432) may bend down and the substrate S may be conveyed in the bent state under the target 21. Both end areas of the substrate S in the axial direction may be positioned lower than the center portion, so that the distance from the target 21 increases.

In FIG. 9, the distance between the center portion of the substrate S and the target 21 is indicated by G4 and the distances between both ends of the substrate and the target 21 are indicated by G31, G32, and G33. The distances between the substrate S and the target 21 may satisfy the conditions, G4<G31, G4<G32, and G4<G33.

Further, the variable diameter portions 432 of the third rollers 43 may have a minimum diameter that decreases for the third rollers 43 closer to the center of the variable roller unit 360. Thus, the degree of bending at both end areas of the substrate S seated on the third rollers 43 (which areas correspond to the variable diameter portions 432) may have a maximum value at the center of the variable roller unit 360, and may have smaller values farther from the center of the variable roller unit 360.

The distance between the substrate S and the target in FIG. 9 may satisfy the condition, G33>G32>G31. Further, both end areas of the substrate S seated on the third rollers 43 (which areas correspond to the variable diameter portions 432) may bend down and then bend up in the conveying direction (x-axial direction).

When a thin film is deposited by using the sputtering unit without the variable roller unit 360, the thicknesses of the thin film measured at both ends of the substrate S may be thicker than the thickness of the thin film measured at the center portion.

The sputtering device according to an embodiment that includes the variable roller unit 360 may make the thicknesses of the thin film measured at both ends of the substrate S relatively thin, and thus the thicknesses of the thin film formed on the center portion and both ends may be uniform. Accordingly, the sputtering device according to an embodiment may increase the deposition uniformity of the thin film in the axial direction (y-axial direction) by using the variable roller unit 360.

Further, the variable diameter portions 432 of the variable roller unit 360 may also bend both end areas of the substrate in the conveying direction (x-axial direction), and thus a large-sized and/or thin substrate may be smoothly conveyed.

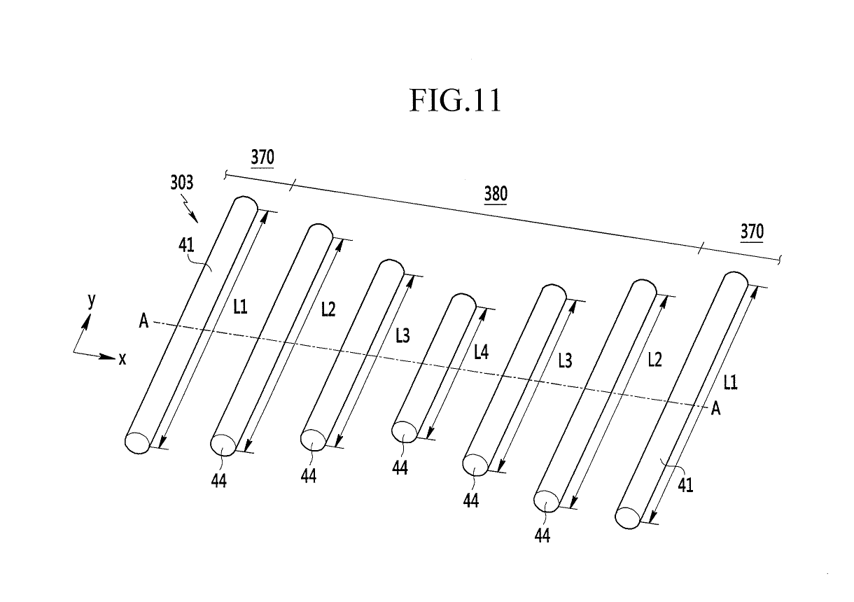

FIG. 11 illustrates a schematic perspective view showing a conveying unit in a sputtering device according to an embodiment. Aspects of the sputtering device illustrated in FIG. 11 may be the same as the aspects of the sputtering device discussed above, and a detailed description of these aspects will not be repeated.

Referring to FIG. 11, a conveying unit 303 may include fixed roller units 370 and a variable roller unit 380. The fixed roller units 370 may include two or more first rollers 41 and may have the same configuration as discussed above. The lengths of the first rollers 41 are indicated by L1 in FIG. 8.

The variable roller unit 380 may include three or more fourth rollers 44. The fourth rollers 44 may have lengths that are shorter than the length of the first rollers 41, and the lengths of the fourth rollers 44 may decrease for the fourth rollers 44 closer to the center of the variable roller unit 380 (farther from the first rollers 41).

The first rollers 41 and the fourth rollers 44 may all have the same diameter. Further, assuming center points C that divide the first rollers 41 and the fourth rollers 44 in two equal parts in the axial direction (y-axial direction), the center points C of the first rollers 41 and the fourth rollers 44 may be positioned in a straight line in the conveying direction. An imaginary line connecting the center points is indicated by a line A-A in FIG. 11.

Although FIG. 11 shows an example when the variable roller unit 380 is composed of five fourth rollers 44, the number of fourth rollers 44 may be a suitable number other than five. The fourth rollers 44 shown in FIG. 11 have lengths L2, L3, L4, L3, and L2 in the conveying direction (x-axial direction) and the lengths may satisfy the condition, L1>L2>L3>L4.

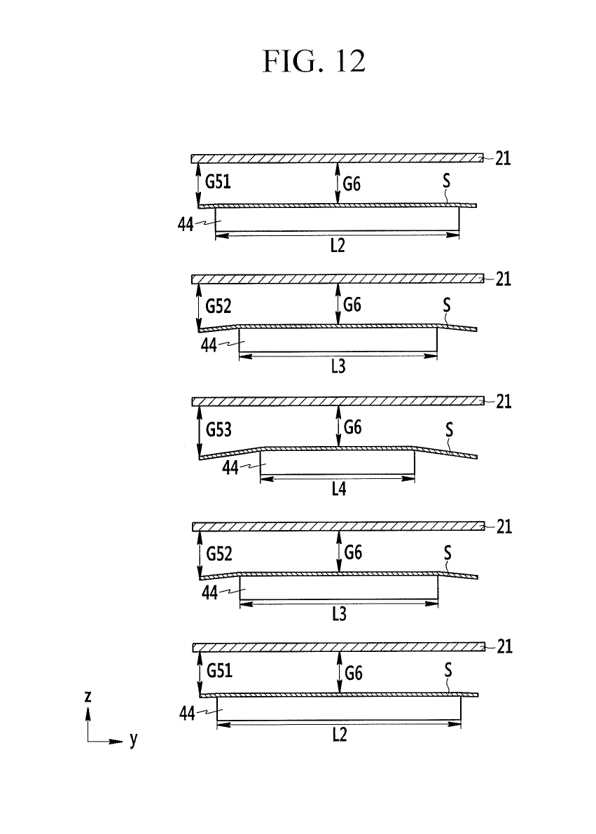

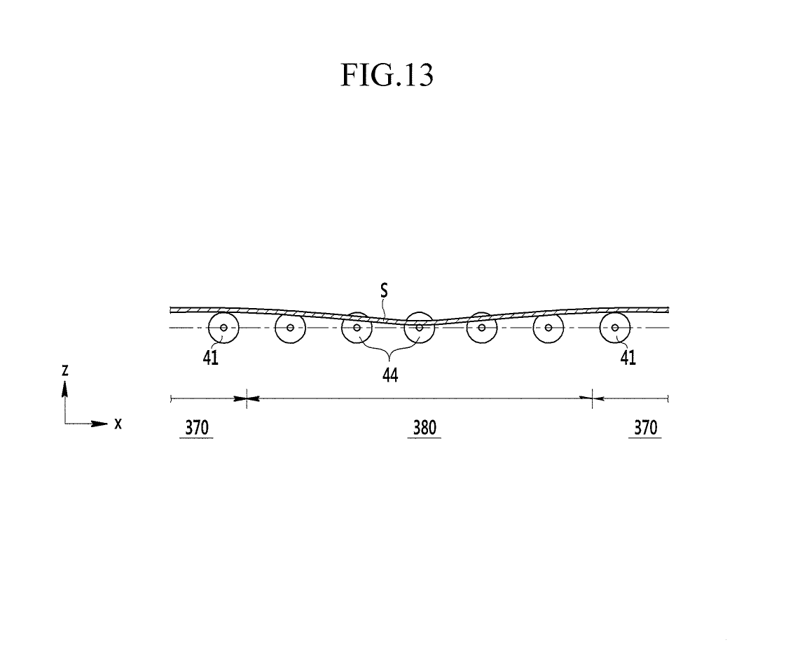

FIG. 12 illustrates a schematic view showing a variable roller unit, a substrate, and a target in the sputtering device of FIG. 11 in the axial direction; FIG. 13 illustrates a schematic view showing the variable roller unit and the substrate in the sputtering device of FIG. 11 in the conveying direction.

Referring to FIGS. 12 and 13, the lengths of fourth rollers 44 may be smaller than the length of a target 21 in the axial direction (y-axial direction). Both ends of a substrate S seated on a variable roller unit 380 may not be completely supported by the fourth rollers 44 and thereby may be suspended in the air, and thus both ends thereof may sag down under their own weight. Thus, both ends of the substrate S may bend down and the substrate S may be conveyed in the bent state under the target 21. Both end areas of the substrate S in the axial direction (y-axial direction) may be positioned lower than the center portion thereof, so that the distances from the target 21 increase.

In FIG. 12, the distance between the center portion of the substrate S and the target 21 is indicated by G6 and the distances between both ends of the substrate and the target 21 are indicated by G51, G52, and G53. The distances between the substrate S and the target 21 may satisfy the conditions, G51>G6, G52>G6, and G53>G6.

Further, the degree of bending at both end areas of the substrate S may have a maximum value at the center of the variable roller unit 380, and may have smaller values farther from the center of the variable roller unit 380. The distance between the substrate S and the target in FIG. 12 may satisfy the condition, G53>G52>G51. Further, both end areas of the substrate S may bend down and then bend up in the conveying direction (x-axial direction).

When a thin film is deposited by using the sputtering unit without the variable roller unit 380, the thicknesses of the thin film measured at both ends of the substrate S may be thicker than the thickness of the thin film measured at the center portion.

The sputtering device according to an embodiment that includes the variable roller unit 380 may make the thicknesses of the thin film measured at both ends of the substrate S relatively thin, and thus the thicknesses of the thin film formed on the center portion and both ends may be uniform. Accordingly, the sputtering device according to an embodiment may increase the deposition uniformity of the thin film in the axial direction (y-axial direction) by using the variable roller unit 380.

As described above, the sputtering devices 100 according to embodiments may include the variable roller units 320, 340, 360, and 380 in which at least one selected from the group of length and diameter changes in the axial direction (y-axial direction), and thus the substrate S may be bent in the axial direction (y-axial direction) under the target 21. Thus, deposition uniformity in the direction (y-axial direction) perpendicular to the conveying direction (x-axial direction) may be increased in the in-line type sputtering device 100, and as a result, the deposition quality of the thin film may be improved.

Meanwhile, although the rollers having the simplest shape were exemplified above, the conveying units 30, 301, 302, and 303, the fixed roller units 310, 330, 350, and 370, and the variable roller units 320, 340, 360, and 380 may be composed of a suitable type of roller having a shape that is applied to roller conveyers. For example, a ring belt type roller using an O-ring and a wheel type roller equipped with a plurality of wheel-shaped rollers on a shaft having a predetermined diameter may be used. For the wheel type roller, the plurality of wheel-shaped rollers may satisfy the shape conditions according to the embodiments described above.

By way of summary and review, a sputtering device may be used in a process of manufacturing the light absorbing layer of a CIGS solar cell (e.g., by a method of sequentially sputtering copper, indium, and gallium on a substrate, evaporating and depositing selenium, and then performing heat treatment). In this process, a thin film (e.g., a light absorbing layer) may be formed on the substrate while conveying the substrate with a conveying device, such as a roller, under a target (i.e., an in-line type process).

However, in the in-line type process, deposition uniformity may be deteriorated in the direction perpendicular to the conveying direction of the substrate. That is, although the deposition uniformity of the thin film may be excellent in the conveying direction, the deposition uniformity may be deteriorated at both ends of the substrate in the direction perpendicular to the conveying direction, for example, the thin film at both ends of the substrate may be formed thick or thin in relation to the center portion thereof.

As explained above, the sputtering device according to an embodiment may increase deposition uniformity of a thin film and/or smoothly convey a substrate. That is, the sputtering device according to an embodiment may include a variable roller unit configured such that the substrate moving under the target is bent up or down at both ends in the axial direction. Thus, deposition uniformity of a thin film in the axial direction may be increased. Also, the sputtering device according to an embodiment may be configured to bend the substrate in the conveying direction, and thus the substrate may be smoothly conveyed.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, aspects described in connection with a particular embodiment may be used singly or in combination with aspects described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A sputtering device, comprising:
a chamber providing a reaction space;
a sputter unit including a target disposed in the chamber; and
a conveying unit including a plurality of rollers for supporting a substrate and for conveying the substrate relative to the target along a first direction,
the conveying unit including:
fixed roller units having a predetermined diameter; and
a variable roller unit having a diameter that changes in a second direction at both ends thereof, the second direction being orthogonal to the first direction.

2. The sputtering device as claimed in claim 1, wherein:
the variable roller unit is positioned directly across from target,
the fixed roller units are positioned at both sides of the variable roller unit in the first direction, and
the fixed roller units include first rollers, each of the first rollers having the predetermined diameter.

3. The sputtering device as claimed in claim 2, wherein the variable roller unit includes at least three second rollers, and
each of the second rollers has:
a fixed diameter portion, and
variable diameter portions connected to both ends of the fixed diameter portion, the variable diameter portions having a diameter that increases for the variable diameter portions farther from the fixed diameter portion.

4. The sputtering device as claimed in claim 3, wherein a maximum diameter of the variable diameter portions increases for the second rollers closer to a center of the variable roller unit.

5. The sputtering device as claimed in claim 3, wherein the fixed diameter portion has a diameter that is less than or equal to the predetermined diameter.

6. The sputtering device as claimed in claim 2, wherein the variable roller unit includes at least three third rollers, and
each of the third rollers has:
a fixed diameter portion, and
variable diameter portions connected to both ends of the fixed diameter portion, the variable diameter portions having a diameter that decreases for the variable diameter portions farther from the fixed diameter portion.

7. The sputtering device as claimed in claim 6, wherein a minimum diameter of the variable diameter portions decreases for third rollers closer to a center of the variable roller unit.

8. The sputtering device as claimed in claim 6, wherein the fixed diameter portion has a diameter that is the predetermined diameter.

9. The sputtering device as claimed in claim 1, wherein a maximum diameter of the variable roller unit is the predetermined diameter.

10. The sputtering device as claimed in claim 1, wherein a minimum diameter of the variable roller unit is the predetermined diameter.

11. The sputtering device as claimed in claim 1, wherein a center of a rotational axis of the fixed roller units and a center of a rotational axis of the variable roller unit are at the same height in a third direction, and the third direction is orthogonal to the first and second directions.

12. The sputtering device as claimed in claim 1, wherein the fixed roller units and the variable roller unit have a same length along the second direction.

13. A sputtering device, comprising:
a chamber providing a reaction space;
a sputter unit including a target disposed in the chamber; and
a conveying unit including a plurality of rollers for supporting a substrate and for conveying the substrate relative to the target along a first direction,
the conveying unit including:
fixed roller units having a predetermined length along a second direction, the second direction being orthogonal to the first direction; and
a variable roller unit having at least two lengths along the second direction that are different from the predetermined length.

14. The sputtering device as claimed in claim 13, wherein:
the variable roller unit is positioned directly across from target,
the fixed roller units are positioned at both sides of the variable roller unit in the first direction, and
the fixed roller units include first rollers, each of the first rollers having the predetermined length.

15. The sputtering device as claimed in claim 14, wherein:
the variable roller unit includes at least three fourth rollers, the fourth rollers having a length shorter than the predetermined length, and
the fourth rollers have a diameter that decreases for the fourth rollers closer to a center of the variable roller unit.

16. The sputtering device as claimed in claim 14, wherein:
the variable roller unit includes at least three fourth rollers, the fourth rollers having a length shorter than the predetermined length, and
a diameter of the first rollers is the same as a diameter of the fourth rollers.

17. The sputtering device as claimed in claim 14, wherein centers of the first rollers and the fourth rollers in the second direction are positioned in a straight line in the first direction.

18. A sputtering device, comprising:
a chamber providing a reaction space;
a sputter unit including a target disposed in the chamber; and
a conveying unit including a plurality of rollers for supporting a substrate, and for conveying the substrate relative to the target in a first direction,
the conveying unit including a variable roller unit, and being configured to bend the substrate in a second direction, the second direction being orthogonal to the first direction.

19. The sputtering device as claimed in claim 18, wherein the variable roller unit is positioned directly across from target.

20. The sputtering device as claimed in claim 18, wherein at least one selected from the group of a length and a diameter of the variable roller unit changes in the second direction.
